(19) United States
(12) Patent Application Publication
(10) Pub. No.: US 2025/0040323 A1
(43) Pub. Date: Jan. 30, 2025

(54) ELECTRONIC DEVICE

(71) Applicant: InnoLux Corporation, Miao-Li County (TW)

(72) Inventors: Yu-Ding LIN, Miao-Li County (TW); Hua-Pin CHEN, Miao-Li County (TW); Shuai WANG, Miao-Li County (TW); Chien-Hao KUO, Miao-Li County (TW)

(21) Appl. No.: 18/751,592

(22) Filed: Jun. 24, 2024

(30) Foreign Application Priority Data
Jul. 24, 2023 (CN) 202310910804.4

(51) Int. Cl. H01L 33/60; H01L 25/075

(52) U.S. Cl. CPC H01L 33/60; H01L 25/0753

(57) ABSTRACT

An electronic device is provided. The electronic device includes: a first substrate, a first light-emitting unit, a wall structure, and a first optical film. The first light-emitting unit is disposed on the first substrate. The wall structure is disposed on the first substrate, and includes a first opening corresponding to the first light-emitting unit. At least a portion of the first optical film is disposed on the first light-emitting unit, and the at least a portion of the first optical film is disposed in the first opening.

### CROSS-REFERENCE TO RELATED APPLICATIONS

This application claims the benefits of the Chinese Patent Application Serial Number 202310910804.4, filed on Jul. 24, 2023, the subject matter of which is incorporated herein by reference.

### BACKGROUND

### Field of the Disclosure

The present disclosure relates to an electronic device and, more particularly, to an electronic device equipped with light-emitting units.

### Description of Related Art

Electronic devices equipped with light-emitting units, such as backlight modules, may improve the contrast of the screen through partition control. However, the halo problems often occur when performing partition control, such as light leakage from a light-emitting area to a non-light-emitting area, and this problem is more serious in backlight module structures where light-emitting units are closely arranged, such as direct-type backlight modules.

Therefore, it is desired to have an electronic device to alleviate and/or obviate the above problems.

### SUMMARY

The present disclosure provides an electronic device, which includes: a first substrate; a first light-emitting unit disposed on the first substrate; a wall structure disposed on the first substrate and provided with a first opening corresponding to the first light-emitting unit; and a first optical film, wherein at least a portion of the first optical film is disposed in the first opening, and at least a portion of the first optical film disposed in the first opening is disposed on the first light-emitting unit.

Other novel features of the disclosure will become more apparent from the following detailed description when taken in conjunction with the accompanying drawings.

### BRIEF DESCRIPTION OF DRAWINGS

FIG. 1 is a schematic diagram of an electronic device according to an embodiment of the present disclosure;

FIG. 2A is a cross-sectional view of an electronic device according to an embodiment of the present disclosure;

FIG. 2B is a detailed structural diagram of the first substrate and the light-emitting unit according to an embodiment of the present disclosure;

FIG. 3 is a cross-sectional view of an electronic device according to another embodiment of the present disclosure;

FIG. 4 is a cross-sectional view of an electronic device according to another embodiment of the present disclosure;

FIG. 5 is a cross-sectional view of an electronic device according to another embodiment of the present disclosure;

FIG. 6 is a cross-sectional view of an electronic device according to another embodiment of the present disclosure;

FIG. 7 is a cross-sectional view of an electronic device according to another embodiment of the present disclosure;

FIG. 8 is a schematic diagram of a wall structure and a first optical film according to an embodiment of the present disclosure; and

FIG. 9 is a schematic diagram of an electronic device according to another embodiment of the present disclosure.

### DETAILED DESCRIPTION OF EMBODIMENT

The following disclosure provides many different embodiments or examples for implementing different components in the provided display device. Specific examples of each component and its configuration are described below to simplify the embodiments of the present disclosure. Of course, these are only examples and are not intended to limit the present disclosure. For example, if the description mentions that a first component is formed on a second component, it may include an embodiment in which the first and second components are in direct contact, or may include an additional component formed between the first and second components, so that they are not in direct contact. In addition, embodiments of the present disclosure may repeat component symbols and/or characters in different examples. This repetition is for the sake of brevity and clarity, and is not intended to indicate the relationship between the different embodiments and/or forms discussed.

Directional terms mentioned in the specification, such as “up”, “down”, “front”, “rear”, “left”, “right”, etc., only refer to the directions of the drawings. Accordingly, the directional term used is illustrative, not limiting, of the present disclosure.

In some embodiments of the present disclosure, the terms related to joining and connecting, such as “connection”, “interconnection” and the like, unless otherwise defined, may refer to two structures in direct contact, or may also refer to two structures not in direct contact in which there are other structures located between the two structures. The terms related to joining and connecting may also include the situation where two structures are movable or two structures are fixed. In addition, the terms “electrical connection” and “coupling” include any direct and indirect electrical connecting means.

In the specification and claims, unless otherwise specified, ordinal numbers, such as “first” and “second”, used herein are intended to distinguish elements rather than disclose explicitly or implicitly that names of the elements bear the wording of the ordinal numbers. The ordinal numbers do not imply what order an element and another element are in terms of space, time or steps of a manufacturing method. Thus, what is referred to as a “first element” in the specification may be referred to as a “second element” in the claims. The terms, such as “about”, “equal”, “is equal to”, “same”, “substantially” or “approximately”, are generally interpreted as within 10% of a given value or range, or as within 5%, 3%, 2%, 1%, or 0.5% of a given value or range.

Furthermore, any two values or directions used for comparison may have certain errors. If the first direction is perpendicular or “substantially” perpendicular to the second direction, the angle between the first direction and the second direction may be between 80 degrees and 100 degrees. If the first direction is parallel or “substantially” parallel to the second direction, the angle between the first direction and the second direction may be between 0 degrees and 10 degrees.

Unless otherwise defined, all terms (including technical and scientific terms) used here have the same meanings as commonly understood by those skilled in the art of the present disclosure. It is understandable that these terms, such as those defined in commonly used dictionaries, should be interpreted as having a meaning consistent with the relevant technology and the background or context of the present disclosure, rather than in an idealized or excessively formal interpretation, unless specifically defined.

Some variations of the embodiments are described below. Similar reference numbers are used to identify similar components in the various drawings and illustrated embodiments. It is understood that additional operations may be provided before, during, and after the method, and some of the described operations may be replaced or deleted for other embodiments of the method.

It should be understood that, according to the disclosed embodiments, an optical microscope (OM), a scanning electron microscope (SEM), a transmission electron microscope (TEM), a film thickness profilometer (α-step), an ellipsometer thickness gauge, or other suitable means may be used to measure the depth, thickness, width or height of each component, or the spacing or distance between components. According to some embodiments, a scanning electron microscope may be used to obtain a cross-sectional structure image including the components to be measured, and measure the depth, thickness, width or height of each component, or the spacing or distance between components.

In the present disclosure, the electronic device may include a backlight device, a display device, an antenna device, a sensing device or a tiled device, but not limited thereto. The electronic device may be a bendable or flexible electronic device. The display device may be a non-self-luminous display device or a self-luminous display device. The antenna device may be a liquid crystal type antenna device or a non-liquid crystal type antenna device, and the sensing device may be a sensing device that senses capacitance, light, heat energy or ultrasonic waves, but not limited thereto. The backlight device may include electronic components. The electronic components may include passive components and active components, such as capacitors, resistors, inductors, diodes, transistors, etc. The diodes may include light emitting diodes or photodiodes. The light emitting diode may include, for example, an organic light emitting diode (OLED), a sub-millimeter light emitting diode (mini LED), a micro light emitting diode (micro LED) or a quantum dot light emitting diode (quantum dot LED), but not limited thereto. The tiled device may be, for example, a display tiled device or an antenna tiled device, but not limited thereto. It should be noted that the electronic device may be any combination of the above, but not limited thereto. In the following, a backlight device is used as an electronic device to illustrate the disclosure, but the present disclosure is not limited thereto.

In addition, the shape of the electronic device may be, for example, a rectangle, a circle, a polygon, a shape with curved edges, a curved surface, or other suitable shapes. The electronic device may have peripheral systems such as a drive system, a control system, a light source system, a shelf system, etc. It should be noted that the electronic device may be any combination of the above, but it is not limited thereto.

It should be noted that the electronic device may be any combination of the above, but not limited thereto. It should be noted that the following embodiments may be replaced, reorganized, and mixed with features of several different embodiments to complete other embodiments without departing from the spirit of the present disclosure. Features in various embodiments may be mixed and matched as long as they do not violate the spirit of the disclosure or conflict with each other.

Unless otherwise defined, all terms (including technical and scientific terms) used herein have the same meaning as commonly understood by those skilled in the art related to the present disclosure. It can be understood that these terms, such as those defined in commonly used dictionaries, should be interpreted as having meaning consistent with the relevant technology and the background or context of the present disclosure, and should not be interpreted in an idealized or excessively formal way. Unless there is a special definition in the embodiment of the present disclosure.

It is emphasized again that terms such as “first”, “second” and so on in this article are only used to distinguish components, and their order has nothing to do with process order.

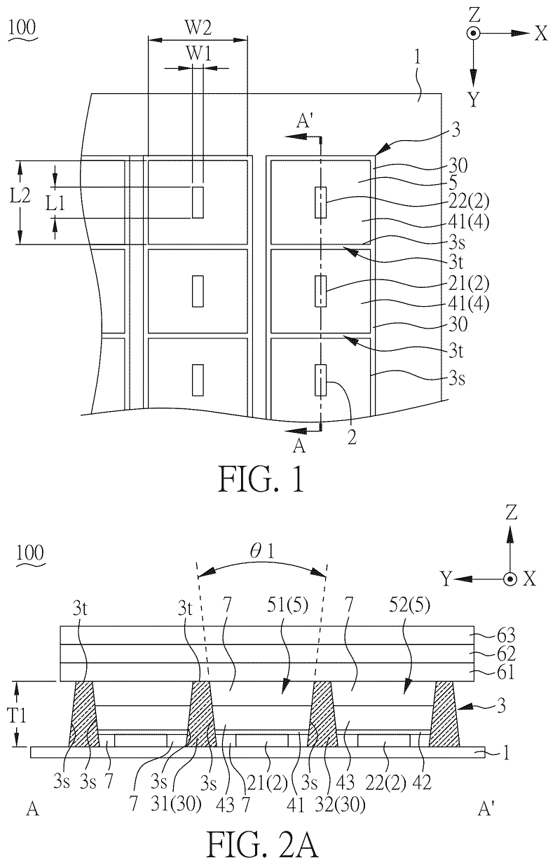

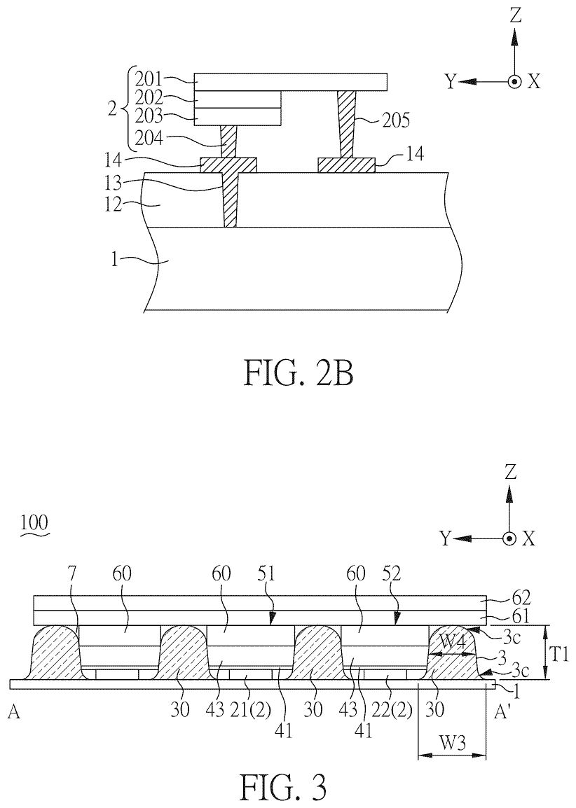

Please refer to FIG. 1 and FIG. 2A. FIG. 1 is a schematic diagram of an electronic device 100 according to an embodiment of the present disclosure, which is presented in a top view. FIG. 2A is a cross-sectional view of the electronic device 100 according to an embodiment of the present disclosure, which shows the cross-section of the electronic device 100 corresponding to the A-A′ cross-section line in FIG. 1. In addition, for clear description, FIG. 1 does not show components, such as the optical film 61, the optical film 62, or the optical film 63 (shown in FIG. 2).

As shown in FIG. 1 and FIG. 2A, the electronic device 100 includes a first substrate 1, a plurality of light-emitting units 2, a wall structure 3 and at least one optical film 4. The plurality of light-emitting units 2 are arranged on the first substrate 1. The wall structure 3 has a plurality of side walls 30 and a plurality of openings 5, wherein the opening 5 may be formed between the side walls 30. Each opening 5 may correspond to at least one light-emitting unit 2. In one embodiment, the type of the first substrate 1 may be a rigid substrate or a flexible substrate, and the material thereof may include glass, polyimide (PI), polyethylene terephthalate (PET) or other suitable materials, or any combination of the above, while it is not limited thereto.

Furthermore, the light-emitting unit 2 may include a first light-emitting unit 21, which is disposed on the first substrate 1. The opening 5 of the wall structure 3 may include a first opening 51, wherein the first opening 51 corresponds to the first light-emitting unit 21. For example, in the top view direction (−Z) of the electronic device 100, the first light-emitting unit 21 is disposed in the first opening of 51. In one embodiment, the position of the first light-emitting unit 21 in the first opening 51 is not limited. For example, it may be located in the middle position, but it may also be located in other positions. In addition, the optical film 4 may include an optical film 41. In the normal direction (Z) of the electronic device 100, at least a portion of the optical film 41 may be disposed in the first opening 51, and at least a portion of the optical film 41 disposed in the first opening 51 may be disposed on the first light-emitting unit 21.

Next, the details of each component will be described.

First, the light-emitting unit 2 of the electronic device 100 will be described. In one embodiment, the light-emitting unit 2 may be, for example, a light-emitting diode or a photodiode, while it is not limited thereto. When the light-emitting unit 2 is a light-emitting diode, the type of the light-emitting unit 2 may include an organic light-emitting diode (OLED), a sub-millimeter light-emitting diode (mini LED), a micro light-emitting diode (micro LED) or a quantum dot light-emitting diode (quantum dot LED), but it is not limited thereto. In one embodiment, the size (e.g., width) of the sub-millimeter light-emitting diode may be between 100 microns and 300 microns (100 μm≤size≤300 μm), but it is not limited thereto. In one embodiment, the size (e.g., width) of the micro LED may be between 1 millimeter and 100 millimeter (1 mm≤size≤100 mm), but it is not limited thereto. For convenience of explanation, the light-emitting unit 2 will be exemplified by a sub-millimeter light-emitting diode (mini LED) in the following, and the electronic device 1 may be, for example, a backlight device using direct-type sub-millimeter light-emitting diode technology, but it is not limited thereto.

The detailed structures of the first substrate 1 and the light-emitting unit 2 are described here. FIG. 2B is a detailed structural diagram of the first substrate 1 and the light-emitting unit 2 according to an embodiment of the present disclosure, and please refer to FIG. 1 and FIG. 2A at the same time. As shown in FIG. 2B, the light-emitting unit 2 may include a first semiconductor layer 201, an active layer 202, a second semiconductor layer 203, a first electrode 204 and a second electrode 205. In one embodiment, in the Z direction, the active layer 202 may be disposed between the first semiconductor layer 201 and the second semiconductor layer 203, the first electrode 204 is electrically connected to the second semiconductor layer 203, and the second electrode 205 is electrically connected to the first semiconductor layer 201, but it is not limited thereto. In addition, at least one insulation layer 12 is provided between the first substrate 1 and the light-emitting unit 2. In one embodiment, a plurality of conductive pads 14 are provided on the insulation layer 12, and the first electrode 204 and the second electrode 205 of the light-emitting unit 2 may be respectively electrically connected to one of the conductive pads 14. In addition, at least one of the conductive pads 14 may be electrically connected to an active component (not shown), such as a transistor or a driver chip, through a conductive channel 13 (such as a conductive via), but it is not limited thereto. The active component may include the following semiconductor materials. The semiconductor materials may include, for example, silicon carbide (SiC), silicon (Si), germanium (Ge), gallium arsenide (GaAs), indium phosphide (InP), gallium nitride (GaN), other suitable materials, or a combination thereof. The semiconductor material may include, for example, low temperature polysilicon (LTPS), low temperature polysilicon oxide (LTPO) or amorphous silicon (a-Si), but it is not limited thereto. The semiconductor materials may include, but not limited to, amorphous silicon, polycrystalline silicon, germanium, compound semiconductor (e.g., gallium nitride, silicon carbide, gallium arsenide, gallium phosphide, indium phosphide, indium arsenide, and/or indium antimonide), alloy semiconductor (such as silicon germanium (SiGe) alloy, gallium arsenic phosphorus (GaAsP) alloy, aluminum indium arsenic (AlInAs) alloy, aluminum gallium arsenic (AlGaAs) alloy, gallium indium arsenic (GaInAs) alloy, gallium indium phosphorus (GaInP) alloy, gallium indium arsenic phosphorus (GaInAsP) alloy, or a combination of the above materials, but it is not limited thereto. The semiconductor materials may include, but not limited to, metal oxide such as indium gallium zinc oxide (IGZO), indium zinc oxide (IZO), indium gallium zinc tin oxide (IGZTO), or organic semiconductor including polycyclic aromatic compound, or a combination of the above materials.

Next, the wall structure 3 and the opening 5 will be described. In one embodiment, the material of the wall structure 3 may be, for example, polycarbonate (PC), polyethylene terephthalate (PET), polymethyl methacrylate (PMMA) or other suitable materials, or any combination of the above, but it is not limited thereto. In addition, the wall structure 3 may be light-transmitting or non-light-transmitting. In one embodiment, the wall structure 3 may be provided with a color, wherein the color of the wall structure 3 may be any color. In one embodiment, the color of the wall structure 3 may be, for example, but not limited to, yellow or white. In one embodiment, the reflectivity of the wall structure 3 may be greater than 85% (85%≤reflectivity), while it is not limited thereto.

The side walls 30 of the wall structure 3 may or may not be connected to each other; for example, two adjacent openings 5 may share the same side wall 30, or may not share the same side wall. In one embodiment, the shape of the opening 5 may be any shape, such as rectangle, circle, triangle, polygon, etc., but it is not limited thereto. In addition, in one embodiment, the side wall 30 may have a side surface 3s and an upper surface 3t, wherein the side surface 3s may be connected to the upper surface 3t, and the upper surface 3t may be in contact with the optical film 4, but it is not limited thereto.

As shown in FIG. 1, the size of the opening 5 may be adjusted according to the size or number of the light-emitting units 2 in the opening 5. For example, the first opening 51 may be adjusted according to the size of the first light-emitting unit 21, and the “size” about the component may, for example, refer to the width or area of the component, but it is not limited thereto. In one embodiment, in the top view direction (−Z) of the electronic device 100, the first light-emitting unit 21 has a first width W1 in a first direction (for example, X), and the first opening 51 has a first opening width W2 in the first direction (X), wherein the first direction (X) is perpendicular to the normal direction (Z) of the electronic device 100. In one embodiment, the first opening width W2 may be 2 to 30 times of the first width W1 (2*W1≤W2≤30*W1), while it is not limited thereto. In one embodiment, the first opening width W2 may be 2 to 6 times of the first width W1 (2*W1≤W2≤6*W1), while is not limited thereto. In this embodiment, the width may be measured corresponding to the side wall of the wall structure. The range design of the aforementioned first width W1 or first opening width W2 is advantageous in that it may be applied to the placement of the optical film after cutting, or it may be applied to the optimal recovery efficiency of the light path of the light-emitting unit 2 so as to achieve the brightness gain effect.

In another embodiment, in the top view direction (−Z) of the electronic device 100, the first light-emitting unit 21 has a first length L1 in a second direction (for example, Y), and the first opening 51 has a first opening length L2 in the second direction (Y), wherein the second direction (Y) is perpendicular to the normal direction (Z) of the electronic device 100, and the second direction (Y) is different from the first direction (X). In one embodiment, the first opening length L2 may be 2 to 30 times of the first length L1 (2*L1≤L2≤30*L1), while it is not limited thereto. In one embodiment, the first opening length L2 may be 2 to 20 times of the first length L1 (2*L1≤L2≤20*L1), while it is not limited thereto. The range design of the aforementioned first length L1 or first opening length L2 is advantageous in that it may be applied to the placement of the optical film after cutting, or it may be applied to the optimal recovery efficiency of the light path of the light-emitting unit 2 so as to achieve the brightness gain effect.

In addition, as shown in FIG. 2A, in one embodiment, viewed from the cross-section formed by the A-A′ line, the wall structure 3 may include a first side wall 31 and a second side wall 32 that form the first opening 51. In one embodiment, the projection of the first side wall 31 or the second side wall 32 on the cross-section formed by the A-A′ line may be, for example, a trapezoid, but in other embodiments, it may be a rectangle or a triangle, or other suitable shapes, while it is not limited thereto. In one embodiment, the first opening 51 may have a first opening angle θ1 when viewed from the cross-section formed by the A-A′ line. The first opening angle θ1 may be defined as the angle formed by the tangential extension line of the side surface 3s of the first side wall 31 adjacent to the first opening 51 and the tangential extension line of the side surface 3s of the second side wall 32 adjacent to the first opening 51, but it is not limited thereto. In one embodiment, the first opening angle θ1 may be between 70 degrees and 170 degrees (70°≤θ1≤170°), but it is not limited thereto. In one embodiment, the first opening angle θ1 may be between 65 degrees and 165 degrees (65°≤θ1≤165°), but it is not limited thereto. In one embodiment, the first opening angle θ1 may be between 60 degrees and 160 degrees (60°≤θ1≤160°), but it is not limited thereto. The aforementioned opening angle design is advantageous in that it may be suitable for controlling the light expansion and concentration for the light emitted by the light-emitting unit 2.

In addition, in one embodiment, in the normal direction (Z) of the electronic device 100, the side wall 30 of the wall structure 3 may have a first thickness T1 (which may be regarded as the height of the wall structure 3). In one embodiment, the first thickness T1 may be smaller than or equal to 6 millimeters (mm), that is, T1≤6 mm. In one embodiment, the first thickness T1 may be between 0.1 mm and 8 mm (0.1 mm≤T1≤8 mm), but it is not limited thereto. In one embodiment, the first thickness T1 may be between 0.075 millimeters (mm) and 7 millimeters (0.075 mm≤T1≤7 mm), but it is not limited thereto. In one embodiment, the first thickness T1 may be between 0.05 millimeters (mm) and 6 millimeters (0.05 mm≤T1≤6 mm), but it is not limited thereto. The range design of the first thickness T1 is advantageous in that it may improve the effect of shielding the adjacent light sources, but it is not limited thereto.

Next, the optical film 4 of the electronic device 100 will be described. In one embodiment, the optical film 4 may include a uniform light film, a diffusion film, a blue light transmitting film (BLT), a brightness enhancement film (BEF), a quantum dot (QD) film, a filter film, a phosphor film, etc., while it is not limited thereto. As shown in FIG. 2, an optical film 41 is provided in the wall structure 3 so that the light emitted by the first light-emitting unit 21 may be more convergent and less likely to scatter. Therefore, the brightness quality of the electronic device 100 may be improved. In addition, in the present disclosure, the optical film 4 may be a single-layer structure (the optical film 41 shown in FIG. 2 is a single-layer structure). However, in fact, the optical film 4 may also be a multi-layer structure.

Next, various embodiments of the electronic device 100 will be described, and please refer to FIG. 2A again.

In the embodiment of FIG. 2, the light-emitting unit 2 of the electronic device 100 may further include a second light-emitting unit 22, which is disposed on the first substrate 1. The wall structure 3 also includes a second opening 52. The second opening 52 may be adjacent to the first opening 51. The second opening 52 corresponds to the second light-emitting unit 22. For example, in the top view direction (−Z) of the electronic device 100, the second light-emitting unit 22 is disposed in the second opening 52. In addition, in one embodiment, another optical film 41 may be disposed in the second opening 52 in the top view direction (−Z) of the electronic device 100. The optical film 41 in the second opening 52 may be disposed on the second light emitting unit 22. The details of the second light-emitting unit 22 and the second opening 52 may be known from the description of the first light-emitting unit 21 and the first opening 51, and thus a detailed description is deemed unnecessary. Through the design of the wall structure 3, the wall structure 3 may, for example, form a fence of light. Therefore, when the electronic device 100 performs partition control, for example, when the first light-emitting unit 21 emits light but the second light-emitting unit 22 does not emit light, at least a portion of the light from the first light-emitting unit 21 may be converged in the wall structure 3, thereby reducing the probability of halo generation in the area of the second light-emitting unit 22.

In addition, one or more optical films 4 may also be provided above the wall structure 3. As shown in FIG. 2A, in one embodiment, the optical film 4 of the electronic device 100 further includes an optical film 61, which is disposed on the wall structure 3 and, in the top view direction (−Z) of the electronic device 100, the optical film 61 at least partially overlaps the optical film 41 in the first opening 51 and the optical film 41 in the second opening 52; that is, the optical film 61 may be disposed on the optical film 41 in the first opening 51 and on the optical film 41 in the second opening 52. Furthermore, in one embodiment, in the normal direction (Z) of the electronic device 100, an optical film 62 may also be disposed on the optical film 61, and an optical film 63 may also be disposed on the optical film 62, but it is not limited thereto. In addition, in the top view direction (−Z) of the electronic device 100, the optical film 62 or the optical film 63 may at least partially overlap the optical film 41 in the first opening 51 and the optical film 41 in the second opening 52; that is, the optical film 62 or the optical film 63 may be disposed on the optical film 41 in the first opening 51 and the optical film 41 in the second opening 52. By disposing the optical film 61, the optical film 62 and/or the optical film 63 above the wall structure 3, the visual effect of the electronic device 100 may be improved, for example, the contrast, blemish concealing, or halo reduction may be improved, but it is not limited thereto.

In addition, more optical films 4 may also be provided in the first opening 51 or the second opening 52 of the wall structure 3. In one embodiment, the optical film 4 of the electronic device 100 may further include an optical film 43 disposed in the first opening 51 and, in the normal direction (Z) of the electronic device 100, the optical film 43 in the first opening 51 41 may be disposed between the first light-emitting unit 21 and the optical film 43 in the first opening 51, but it is not limited thereto. In addition, another optical film 43 may also be disposed in the second opening 52 and, in the normal direction (Z) of the electronic device 100, the optical film 41 in the second opening 52 may be disposed between the second light-emitting unit 22 and the optical film 43 in the second opening 52, but it is not limited thereto. The optical film 43 may also provide the effect of improving the brightness quality. In addition, the optical films 4 may be the same or different from each other. For example, in one embodiment, the optical film 41 may be a QD film, the optical film 43 may be a diffusion film, the optical film 61 may be a blue light film (BLT), the optical film 62 and the optical film 63 may be, for example, a brightness enhancement film (BEF), but it is not limited thereto. In addition, in one embodiment, the thicknesses of the optical films 4 (for example, the heights in the Z direction) may be the same or different. For example, the thickness of the optical film 41 may be smaller than the thickness of the optical film 43, while it is not limited thereto.

In one embodiment, when the light-emitting unit 2 of the electronic device 100 is used to emit white light, the type of one or more optical films 4 in the first opening 51 or the second opening 52 may include a diffusion film and a filter film, while it is not limited thereto. In another embodiment, when the light-emitting unit 2 of the electronic device 100 is used to emit blue light, the type of one or more optical films 4 in the first opening 51 or the second opening 52 may include a diffusion film, a filter film and a quantum dot (QD) film, while it is not limited thereto.

In one embodiment, the thickness of the aforementioned optical films 41, 43, 61˜63 in the normal direction (Z) of the electronic device 100 may be adjusted according to needs without limitation.

In addition, in one embodiment, in the normal direction (Z) of the electronic device 100, there may be a gap 7 between the optical film 41 and the optical film 61, where the gap 7 may be, for example, an air layer or other light penetration materials, while it is not limited thereto. In one embodiment, the electronic device 100 may be or may not be provided a gap according to the user's needs, while the present disclosure is not limited thereto. In this embodiment, there may also be a gap 7 between the optical film 43 and the third optical film 61. In one embodiment, the thickness of the gap 7 in the Z direction may be approximately between 1 millimeter and 3 millimeters (1 mm≤thickness of gap 7≤3 mm); for example, it may be approximately 2 millimeters, while it is not limited thereto.

As a result, the embodiment of FIG. 2A can be understood.

The electronic device 100 may also have different implementation aspects. FIG. 3 is a cross-sectional view of an electronic device 100 according to another embodiment of the present disclosure, and please refer to FIG. 1 and FIG. 2A as a reference. Most of the features of the embodiment of FIG. 3 may be applicable to the description of the embodiment of FIG. 2A, and thus the following description will mainly focus on the differences.

As shown in FIG. 3, an optical film 60 is provided in the first opening 51, and another optical film 60 is provided in the second opening 52. In the normal direction (Z) of the electronic device 100, the optical film 60 in the first opening 51 may be disposed between the optical film 61 and the optical film 43 in the first opening 51, and the optical film 60 in the second opening 52 may be disposed between the optical film 61 and the optical film 43 in the second opening 52, but it is not limited thereto. Furthermore, the optical film 43 in the first opening 51 may contact the optical film 61, and the optical film 43 in the second opening 52 may contact the optical film 61. Therefore, there may be no gap between the optical film 43 and the optical film 61, but it is not limited thereto.

In addition, the number of optical films above the wall structure 3 may also be adjusted. In this embodiment, the optical films above the wall structure 3 may include the optical film 61 and the optical film 62, but may not include the optical film 63 in the embodiment of FIG. 2, while it is not limited thereto. In fact, more or less optical films may be provided above the wall structure 3.

In addition, the shape of the wall structure 3 may have different variations. In the embodiment of FIG. 3, viewed from the cross-section formed by the A-A′ line, the wall structure 3 of the embodiment of FIG. 3 may have at least one arc-shaped edge 3c. In addition, the bottom of the wall structure 3 has a width W3 in the horizontal direction (e.g., Y), and the middle portion of the wall structure 3 has a width W4 in the horizontal direction (e.g., Y), wherein the width W3 may be larger than the width W4, but it is not limited thereto. Here, the “bottom” may be regarded as the position of the wall structure 3 adjacent to the first substrate 1, and the “middle portion” may be defined as half the first thickness T1 extending from the bottom of the wall structure 3 along the Z direction. The position; that is, the distance between the “middle portion” and the “bottom” in the Z direction is half the first thickness T1.

As a result, the embodiment of FIG. 3 can be understood.

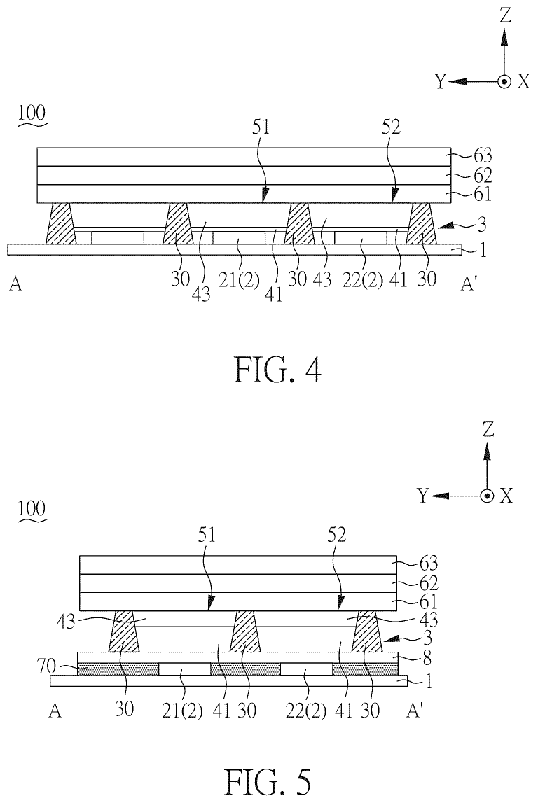

The electronic device 100 may also have different implementation aspects. FIG. 4 is a cross-sectional view of an electronic device 100 according to another embodiment of the present disclosure, and please refer to FIG. 1 to FIG. 3 as a reference. Most of the features of the embodiment of FIG. 4 may be applicable to the description of the embodiment of FIG. 2A, and thus the following description will mainly focus on the differences.

As shown in FIG. 4, in this embodiment, an optical film 43 may be provided in the first opening 51, and another optical film 43 may be provided in the second opening 52. In the normal direction (Z) of the electronic device 100, the optical film 43 in the first opening 51 may be disposed between the optical film 61 and the optical film 41 in the first opening 51, and the optical film 43 in the first opening 51 may contact the optical film 61, The optical film 43 in the second opening 52 may be disposed between the optical film 61 and the optical film 41 in the second opening 52, and the optical film 43 in the second opening 52 may contact the optical film 61. Therefore, there may be no gap between the optical film 43 and the optical film 61, but it is not limited thereto.

As a result, the embodiment of FIG. 4 can be understood.

The electronic device 100 may also have different implementation aspects. FIG. 5 is a cross-sectional view of an electronic device 100 according to another embodiment of the present disclosure, and please refer to FIG. 1 to FIG. 4 as a reference. Most features of the embodiment in FIG. 5 may be applicable to the description of the embodiment in FIG. 2A, and thus the following description will mainly focus on the differences.

As shown in FIG. 5, the electronic device 100 of this embodiment further includes a second substrate 8. In the normal direction (Z) of the electronic device 100, the second substrate 8 may be disposed between the wall structure 3 and the first light-emitting unit 21. In more detail, in the normal direction (Z) of the electronic device 100, the first light-emitting unit 21 may be disposed on the first substrate 1, the second substrate 8 may be disposed on the first light-emitting unit 21, and the wall structure 3 may be disposed on the second substrate 8. Furthermore, the electronic device 100 may also include a second light-emitting unit 22 disposed on the first substrate 1 and, in the normal direction (Z) of the electronic device 100, the second substrate 8 may also be disposed between the second light-emitting unit 22 and the wall structure 3. In one embodiment, the second substrate 8 may at least partially overlap the first light-emitting unit 21 and the second light-emitting unit 22, but it is not limited thereto. In addition, the electronic device 100 further includes at least one glue 70 disposed around the light-emitting unit 2. For example, the glue 70 may surround the first light-emitting unit 21 and the second light-emitting unit 22, so that the second substrate 8 or the optical film 4 may be placed flatly on the glue 70, but it is not limited thereto. In this embodiment, the upper surface of the glue 70 may be substantially aligned with the upper surface of the light-emitting unit 2 so that the second substrate 8 may be placed flatly thereon.

In addition, in this embodiment, an optical film 43 may be provided in the first opening 51, and another optical film 43 may be provided in the second opening 52. In the normal direction (Z) of the electronic device 100, the optical film 41 in the first opening 51 may be disposed between the second substrate 8 and the optical film 43 in the first opening 51. The optical film 43 in the first opening 51 may be disposed between the optical film 61 and the optical film 41 in the first opening 51, and the optical film 41 in the second opening 52 may be disposed between the second substrate 8 and the optical film 43 in the second opening 52. The optical film 43 in the second opening 52 may be disposed between the optical film 61 and the optical film 41 in the second opening 52, but it is not limited thereto. Furthermore, a gap may be or may not be provided between the optical film 43 and the optical film 61 as required.

In one embodiment, the material of the second substrate 8 may be applicable to the description of the first substrate 1, but it is not limited thereto. In another embodiment, the second substrate 8 may be replaced by another optical film 4, while it is not limited thereto.

As a result, the embodiment of FIG. 5 can be understood.

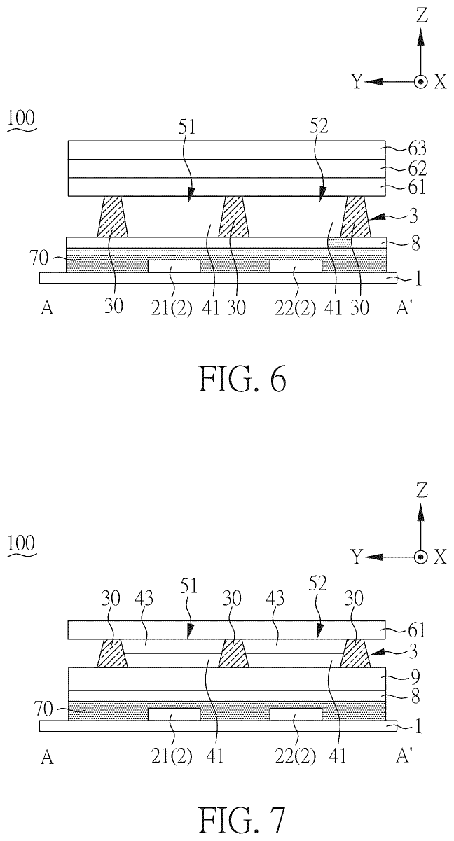

The electronic device 100 may also have different implementation aspects. FIG. 6 is a cross-sectional view of an electronic device 100 according to another embodiment of the present disclosure, and please refer to FIG. 1 to FIG. 5 as a reference. Most of the features of the embodiment in FIG. 6 may be applicable to the description of the embodiment in FIG. 5, and thus the following description will mainly focus on the differences.

The embodiment of FIG. 6 also includes the second substrate 8 in the embodiment of FIG. 5. For details, please refer to the description of the embodiment of FIG. 5, so that a detailed description is deemed unnecessary. In this embodiment, the electronic device 100 may include at least one glue 70, and the glue 70 may cover the light-emitting unit 2. For example, the glue 70 may cover the first light-emitting unit 21 and the second light-emitting unit 22. In the Z direction, the glue 70 may be higher than the light-emitting unit 2. Therefore, the second substrate 8 or the optical film 4 may be placed flatly on the glue 70, but it is not limited thereto. In addition, as shown in FIG. 6, in the normal direction (Z) of the electronic device 100, the optical film 41 in the first opening 51 may be disposed between the second substrate 8 and the optical film 61, and the optical film 41 in the second opening 52 may be disposed between the eighth substrate 8 and the optical film 61, but it is not limited thereto. Furthermore, a gap may be or may not be provided between the optical film 41 and the third optical film 61 as required.

In one embodiment, the number of optical films arranged on the second substrate 8 and disposed in the first opening 51 or the second opening 52 may be adjusted according to the actual needs. As a result, the embodiment of FIG. 6 can be understood.

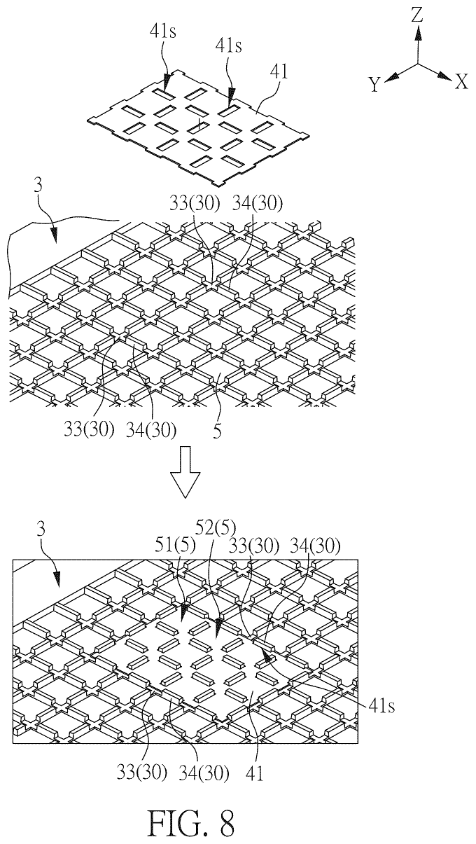

The electronic device 100 may also have different implementation aspects. FIG. 7 is a cross-sectional view of an electronic device 100 according to another embodiment of the present disclosure, and please refer to FIG. 1 to FIG. 6 as a reference. Most features of the embodiment in FIG. 7 may be applicable to the description of the embodiment in FIG. 6, and thus the following description will mainly focus on the differences.

The embodiment of FIG. 7 may also include the second substrate 8 in FIG. 5. In addition, the embodiment of FIG. 7 also includes a third substrate 9, wherein the second substrate 8 may be disposed between the first light-emitting unit 21 and the third substrate 9. In more detail, in the normal direction (Z) of the electronic device 100, the first light-emitting unit 21 may be disposed on the first substrate 1, the second substrate 8 may be disposed on the first light-emitting unit 21, and the third substrate 9 may be disposed on the second substrate 8, and the wall structure 3 may be disposed on the third substrate 9. Furthermore, the electronic device 100 may further include a second light-emitting unit 22 disposed on the first substrate 1 and, in the normal direction (Z) of the electronic device 100, the second substrate 8 may be disposed between the second light-emitting unit 22 and the third substrate 9. In one embodiment, the second substrate 8 may at least partially overlap the first light-emitting unit 21 and the second light-emitting unit 22, and the third substrate 9 may at least partially overlap the first light-emitting unit 21 and the second light-emitting unit 22, but it is not limited thereto.

In one embodiment, the material of the third substrate 9 may be known from the description of the first substrate 1, but it is not limited thereto. In another embodiment, the third substrate 9 may also be replaced by another optical film 4, while it is not limited thereto.

In addition, in this embodiment, the electronic device 100 may include glue 70, and the glue 70 may be placed flatly on the optical film 4, the second substrate 8 or the second substrate 9, while it is not limited thereto. In addition, the first opening 51 of the wall structure 3 is provided with an optical film 41 and an optical film 43, and the second opening 52 of the wall structure 3 is provided with another optical film 41 and another optical film 43. In the normal direction (Z) of the electronic device 100, the optical film 41 in the first opening 51 may be disposed between the third substrate 9 and the optical film 43 in the first opening 51. The optical film 43 in the first opening 51 may be disposed between the optical film 41 in the first opening 51 and the optical film 61 on the wall structure 3, the optical film 41 in the second opening 52 may be disposed between the third substrate 9 and the optical films 43 in the second opening 52, the optical film 43 in the second opening 52 may be disposed between the optical film 61 and the optical film 41 in the second opening 52, but it is not limited thereto. Furthermore, a gap may be or may not be provided between the optical film 43 and the optical film 61 as required. In addition, in one embodiment, the number of the optical films arranged on the third substrate 9 and disposed in the first opening 51 may be adjusted according to the actual needs, or the number of optical films arranged on the third substrate 9 and disposed in the second opening 52 may be adjusted according to the actual needs.

As a result, the embodiment of FIG. 7 can be understood.

The wall structure 3 and the optical film 4 (e.g., the optical film 41) of the present disclosure may also have different implementation aspects. FIG. 8 is a schematic diagram of the wall structure 3 and the optical film 41 according to an embodiment of the present disclosure, and please refer to FIG. 1 to FIG. 7 as a reference. It is noted that most of the features of the embodiment of FIG. 8 may be applicable to the description of the embodiment of FIG. 2, and thus the following description will mainly focus on the differences. In addition, for convenience of explanation, FIG. 8 only shows the wall structure 3 and the optical film 41, but does not show other parts of the electronic device 1.

As shown in FIG. 8, the side wall 30 of the wall structure 3 may have a concave portion 33 and a convex portion 34. In one embodiment, the concave portion 33 may form a flat surface on which the optical film 41 may be placed. In addition, in one embodiment, the optical film 41 may include openings 41s corresponding to the convex portions 34 of the side walls 30. The convex portion 34 of the side wall 30 may pass through the opening 51s of the optical film 41 and, at this moment, the concave portion 33 of the side wall 30 may be used to carry the optical film 41.

In one embodiment, in the top view direction (−Z) of the electronic device 100, the optical film 41 may overlap a plurality of openings 5 (e.g., the first opening 51 and the second opening 52) of the wall structure 3, wherein the optical film 41 may include a plurality of openings 41s respectively corresponding to the plurality of convex portions 34 of the side wall 30. Therefore, when the convex portions 34 of the side wall 30 pass through the openings 41s of the optical film 41, the plurality of the concave portions 33 of the side wall 30 may carry the optical film 41, while it is not limited thereto. At least a portion of the optical film 41 may be disposed in the first opening 51, and at least another portion of the optical film 41 may be disposed in the second opening 52, so that the at least a portion of the optical film 41 may overlap the first light-emitting unit 21 in the first opening 51, and the at least another portion of the optical film 41 may overlap the second light-emitting unit 22 in the second opening 52, while it is not limited thereto.

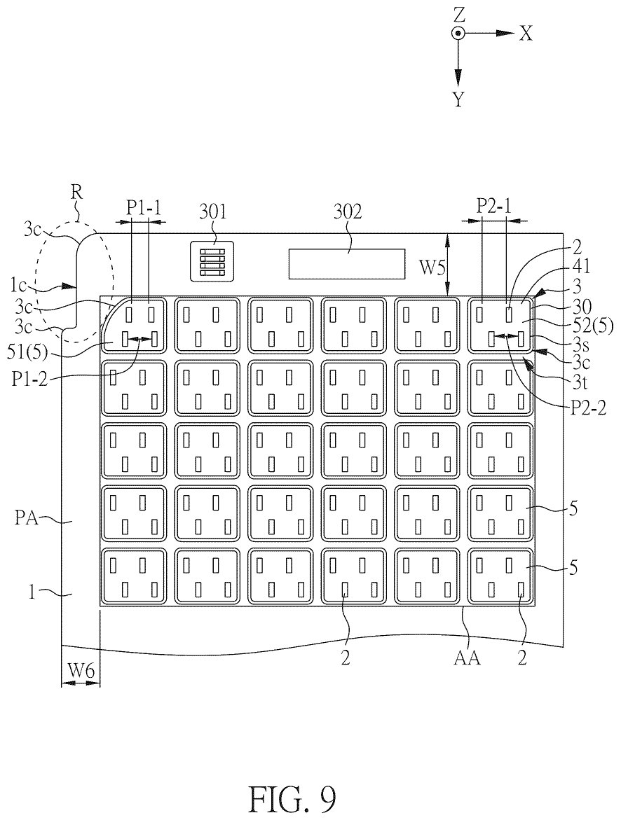

FIG. 9 is a schematic diagram of an electronic device 100 according to another embodiment of the present disclosure, which is presented in a top view, and please refer to FIG. 1 to FIG. 8 at the same time. Some features of the embodiment in FIG. 9 may be applicable to the description of the embodiment in FIG. 1, and thus the following description will mainly focus on the differences. It is noted that the number of light-emitting units 2 or openings 5 as well as the shape and size of the first substrate 1 in FIG. 9 are examples rather than limitations.

As shown in FIG. 9, in one embodiment, a plurality of light-emitting units 2 may be provided in the opening 5, and the arrangement of the light-emitting units 2 in each opening 5 may be the same or different. For example, in the embodiment of FIG. 9, the arrangement of the light-emitting units 2 in the first opening 51 may be different from the arrangement of the light-emitting units 2 in the second opening 52. For example, in a first direction (e.g., X), in the first opening 51 near the corner R in the embodiment of FIG. 9, the spacing P1-1 between two adjacent light-emitting units 2 and the spacing P1-2 between two adjacent light-emitting units 2 are different, while the spacing P2-1 between two adjacent light-emitting units 2 and the spacing P2-2 between two adjacent light-emitting units 2 in the second opening 52 are the same, but it is not limited thereto. The above arrangement design is advantageous in that the light emitted by the light-emitting units at the corners may be adjusted to achieve a brightness gain effect.

In addition, in one embodiment, in the top view direction (−Z) of the electronic device 100, the opening of the wall structure 3 may have an arc-shaped edge 3c, while it is not limited thereto. In one embodiment, the curvature of the arc-shaped edge 3c of the first opening 51 near the corner R is different from the curvature of the arc-shaped edge 3c of the second opening 52. In one embodiment, the shape of each opening 5 may be the same or different. For example, the shape of the first opening 51 near the corner R in the embodiment of FIG. 9 may be different from the shape of the second opening 52, while it is not limited thereto. In one embodiment, the area of the first opening 51 near the corner R is smaller than the area of the second opening 52, while it is not limited thereto. The aforementioned opening design is advantageous in that the light emitted by the light-emitting unit at the corner may be adjusted to achieve a brightness gain effect.

In one embodiment, the electronic device may include an active area AA and a peripheral area PA adjacent thereto. The opening 5 of the wall structure 3 may be disposed in the active area AA, and one or more electronic components, for example, the first electronic component 301 and the second electronic component 302, may be disposed on the first substrate 1 in the peripheral area PA, but it is not limited thereto. In one embodiment, the first electronic component 301 may be a passive component such as an inductor, a resistor, a capacitor, etc., while it is not limited thereto. In one embodiment, the second electronic component 302 may be, for example, an active component such as a transistor or a driver chip, while it is not limited thereto. The first electronic component 301 and the second electronic component 302 may be electrically connected to the light-emitting unit of the active area AA, and the first electronic component 301 and the second electronic component 302 may be disposed in the peripheral area PA on the same side of the active area AA, so that the width of the peripheral area PA on different sides of the active area AA is made different. For example, in the embodiment of FIG. 9, the width W5 of the peripheral area PA where electronic components are installed is greater than the width W6 of the peripheral area PA on different sides corresponding to the active area AA. The aforementioned width design of the peripheral area is advantageous in reducing the use area of the peripheral area and increasing the use area of the active area.

In one embodiment, the edge 1c of the corner R of the first substrate 1 may have any shape, while it is not limited thereto. In one embodiment, for example, the edge 1c of the corner R in the embodiment of FIG. 9 may be close to the active area AA, and the edge 1c may have at least one arc-shaped edge 3c, while it is not limited thereto. The aforementioned edge design is advantageous in reducing the area of the peripheral area PA at the corner R and reducing the collision problem at the corner of the first substrate during the movement of the electronic device.

In one embodiment, the present disclosure may at least compare the operation of an object through mechanical observation, for example, using the operational relationship between components as evidence to prove whether the operation of the object falls within the scope of patent protection of the present disclosure, or a display measurement machine may be used to measure the brightness distribution of the light-emitting surface of the object as a basis for judgment, while is not limited thereto.

As a result, the present disclosure may provide a clear display screen so as to solve the problems of the existing technology.

Details or features of the various embodiments of the present disclosure may be mixed and matched as long as they do not violate the spirit of the invention or conflict with each other.

The aforementioned specific embodiments should be construed as merely illustrative, and not limiting the rest of the present disclosure in any way.

1. An electronic device, comprising:
a first substrate;
a first light-emitting unit disposed on the first substrate;
a wall structure disposed on the first substrate and provided with a first opening corresponding to the first light-emitting unit; and
a first optical film, wherein at least a portion of the first optical film is disposed in the first opening, and at least a portion of the first optical film disposed in the first opening is disposed on the first light-emitting unit.

2. The electronic device as claimed in claim 1, further comprising a second light-emitting unit and a second optical film, wherein the second light-emitting unit is disposed on the first substrate, and the second optical film is disposed on the second light-emitting unit, the wall structure further includes a second opening corresponding to the second light-emitting unit, and the second optical film is disposed in the second opening.

3. The electronic device as claimed in claim 2, further comprising a third optical film disposed on the wall structure, wherein the third optical film at least partially overlaps the first optical film in the first opening and the second optical film in the second opening.

4. The electronic device as claimed in claim 3, further comprising a fourth optical film disposed in the first opening, wherein the fourth optical film is disposed between the first optical film and the third optical film.

5. The electronic device as claimed in claim 3, wherein there is a gap between the first optical film and the third optical film.

6. The electronic device as claimed in claim 1, further comprising a second substrate disposed between the wall structure and the first light-emitting unit.

7. The electronic device as claimed in claim 1, wherein the wall structure has a side wall, the side wall has a concave portion and a convex portion, the first optical film has an opening corresponding to the convex portion of the side wall, and the concave portion of the side wall carries the first optical film.

8. The electronic device as claimed in claim 1, wherein, in a normal direction of the electronic device, the wall structure has a side wall, the side wall has a thickness, and the thickness is between 0.05 mm and 6 mm.

9. The electronic device as claimed in claim 1, wherein, in a top view direction of the electronic device, the first light-emitting unit has a first width in a first direction, the first opening has a first opening width in the first direction, and the first opening width is 2 to 30 times of the first width.

10. The electronic device as claimed in claim 1, wherein, in a top view direction of the electronic device, the first light-emitting unit has a first length in a second direction, the first opening has a first opening length in the second direction, and the first opening length is 2 to 30 times of the first length.

11. The electronic device as claimed in claim 1, wherein a reflectivity of the wall structure is greater than 85%.

12. The electronic device as claimed in claim 1, wherein the wall structure includes a first side wall and a second side wall for forming the first opening having a first opening angle of 70 degrees to 170 degrees.

13. The electronic device as claimed in claim 3, wherein a fifth optical film is disposed on the third optical film, and the fifth optical film at least partially overlaps the first optical film in the first opening.

14. The electronic device as claimed in claim 13, wherein a sixth optical film is disposed on the fifth optical film, and the sixth optical film at least partially overlaps the first optical film 41 in the first opening.

15. The electronic device as claimed in claim 4, wherein there is a gap between the fourth optical film and the third optical film.

16. The electronic device as claimed in claim 4, wherein a seventh optical film is disposed in the first opening, the seventh optical film is disposed between the fourth optical film and the third optical film, and the fourth optical film contacts the third optical film.

17. The electronic device as claimed in claim 4, wherein the fourth optical film in the first opening contacts the third optical film.

18. The electronic device as claimed in claim 1, further comprising a second substrate disposed between the wall structure and the first light-emitting unit; and at least one glue disposed to surround the first light-emitting unit.

19. The electronic device as claimed in claim 1, further comprising a second substrate disposed between the wall structure and the first light-emitting unit; and at least one glue disposed to cover the first light-emitting unit and the second light-emitting unit.

20. The electronic device as claimed in claim 1, further comprising a second substrate and a third substrate, wherein the first light-emitting unit is disposed on the first substrate, the second substrate is disposed on the first light-emitting unit, the third substrate is disposed on the second substrate 8, and the wall structure is disposed on the third substrate.
